(19) United States
(12) Patent Application Publication
(10) Pub. No.: US 2013/0279095 A1
(43) Pub. Date: Oct. 24, 2013

(54) PRINTING PRESS CONTROL STATION

(71) Applicant: MANROLAND WEB SYSTEMS GMBH, Augsburg (DE)

(72) Inventor: Rudolf NAEGELE, Friedberg (DE)

(73) Assignee: manroland web systems GmbH, Augsburg (DE)

(21) Appl. No.: 13/866,775

(22) Filed: Apr. 19, 2013

(30) Foreign Application Priority Data
Apr. 23, 2012 (DE) 10 2012 103 547.4

(51) Int. Cl. H05K 7/00

(52) U.S. Cl. CPC H05K 7/005
USPC 361/679.01

(57) ABSTRACT

A printing press control station is disclosed. The control station includes a support and a display element. The display element is a combined display and operating element for displaying and inputting data. The display element can be shifted along the support. Either the display and operating element or an assembly that can be shifted together with the display and operating element or the support or a housing receiving the support, is assigned at least one sensor which senses a lateral distance of the display and operating element or of the assembly from a lateral portion of the support or the housing. The data displayed and input on/in the display and operating element can be automatically adapted to the relative position of the display element relative to the support sensed by the or each sensor.

This application claims the priority of German Patent Document No. DE 10 2012 103 547.4, filed Apr. 23, 2012, the disclosure of which is expressly incorporated by reference herein.

### BACKGROUND AND SUMMARY OF THE INVENTION

The invention relates to a printing press control station.

From European Patent Document EP 1 381 514 B1 a printing press control station is known, which comprises a support for receiving a print copy. The control station known from this reference additionally comprises a display and operating element, which is formed by a keyboard and a monitor, wherein this display and operating element is fixed in location in its relative position to the support. The control station according to EP 1 381 514 B1 additionally comprises a display element embodied as a display, which can be shifted along a front or operating-side edge of the support relative to the support. A guide rail, on which the display is shiftably mounted, is assigned position sensors in order to determine the relative position of the display. With the control station according to EP 1 381 514 B1, a separate display and operating element, which comprises a keyboard and a display, cannot be omitted. A further disadvantage is that the position sensing of the relative position of the display relative to the support is dependent on the grid of the position sensors in the guide rail, so that accordingly the relative position of the display relative to the support can only be determined inaccurately.

A further printing press control station is known from German Patent Document DE 10 2010 033 740 A1. With this printing press control station, a display and operating device is formed by a multi-touch screen.

Starting out from this, the object of the present invention is based on creating a new type of printing press control station.

According to the invention, the display element is formed as a combined display and operating element for displaying and entering data, wherein either the display and operating element or an assembly that can be shifted together with the display and operating element or the support or a housing receiving the support is assigned at least one sensor, which in shifting direction of the display and operating element senses a lateral distance between the display and operating element or the assembly which is shiftable together with the display and operating element and a lateral portion of the support or the housing receiving the support, wherein the data that can be displayed and entered in the display and operating element can be automatically adapted to the relative position of the display element sensed via the or each sensor relative to the support.

With the printing press control station according to the invention, it is provided for the first time to movably configure a display and operating element relative to the support of the printing press control station and to sense the position of the display and operating element via at least one sensor, wherein the sensor is assigned either to the display and operating element or an assembly which is shiftable together with the display and operating element or the support or a housing receiving the support, in order to sense in this way in shifting direction of the display and operating element a lateral distance of the same from the support or the housing receiving the support. By doing so it is then possible to not only adapt the displayable data but also the enterable data automatically to the relative position of the display and operating element relative to the support sensed by the or each sensor, wherein this relative position can be sensed in any resolution magnitude, so that on the display and operating element data which are exactly matched to each relative position can be displayed and entered.

Preferentially, either the display and operating element or the assembly which is shiftable together with the display and operating element or the housing receiving the support are each assigned two sensors, wherein a first sensor senses the above lateral distance in the shifting direction of the display and operating element and a second sensor senses a corresponding lateral distance in the opposite direction to the shifting direction of the display and operating element. By doing so it is possible to verify the measured relative position of the display and operating element via a comparison of the measurement signals provided by the two sensors. This then makes possible automatic error detection with respect to the functions of the sensors.

According to an advantageous further development of the invention, the display and operating element is designed as a multi-touch screen. The embodiment of the display and operating element as a multi-touch screen is particularly preferred and allows a particularly advantageous display and input of data and utilization of input and display options of a multi-touch screen.

According to an advantageous further development of the invention, the printing press control station comprises at least one soft-proof monitor, which is arranged on an opposite side of the support from the display and operating element in such a manner that the or each soft-proof monitor can be automatically shifted to the relative position of the display and operating element along the edge of the support located opposite from the display and operating element. When the position of the or each soft-proof monitor can be automatically adapted to the relative position of the display and operating element relative to the support, a particularly advantageous operation of the printing press control station is possible.

Preferred further developments of the invention are obtained from the following description. Exemplary embodiments of the invention are explained in more detail by the drawings, without being restricted thereto.

### BRIEF DESCRIPTION OF THE DRAWINGS

FIG. 1 is a schematic, perspective view of an embodiment of a printing press control station according to the principles of the present invention;

FIG. 2 is a detail of the control station of FIG. 1;

FIG. 3 is a cross-sectional view of the control station of FIG. 1;

FIG. 4 is a possible display on the display and operating element of the control station of FIG. 1;

FIG. 5 is a further possible display on the display and operating element of the control station of FIG. 1;

FIG. 6 is a further possible display on the display and operating element of the control station of FIG. 1; and

FIG. 7 is a schematic, perspective view of an alternative embodiment of a printing press control station according to the principles of the present invention.

### DETAILED DESCRIPTION OF THE DRAWINGS

The present invention relates to a printing press control station of a printing press.

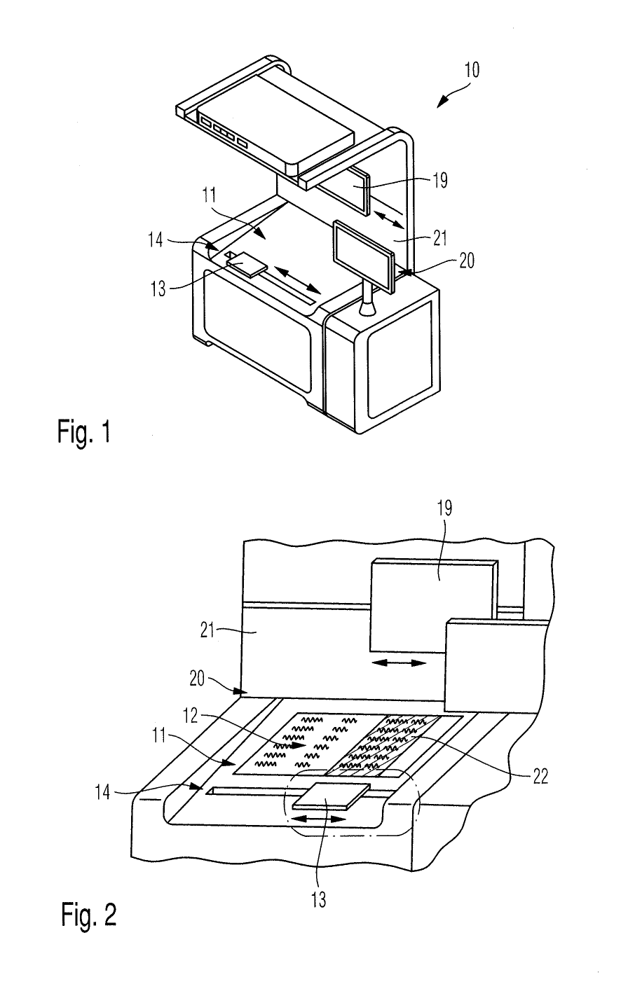

FIG. 1 shows a perspective view of a preferred exemplary embodiment of a printing press control station 10 according to the invention. Such a printing press control station 10 comprises a support 11 for a print copy, in particular for a printed print sheet or a portion of a printed substrate web. FIG. 2 shows a detail of the printing press control station 10, wherein in FIG. 1 on the support 11 a print copy 12 is positioned.

The printing press control station 10 according to the invention comprises a display and operating element 13, which can be shifted along a front or operating-side edge 14 of the support 11 relative to the support 11. The display and operating element 13, which can be shifted relative to the support 11, preferentially is a multi-touch screen, via which data can be displayed and input, wherein details of which will be discussed making reference to FIGS. 4 to 6.

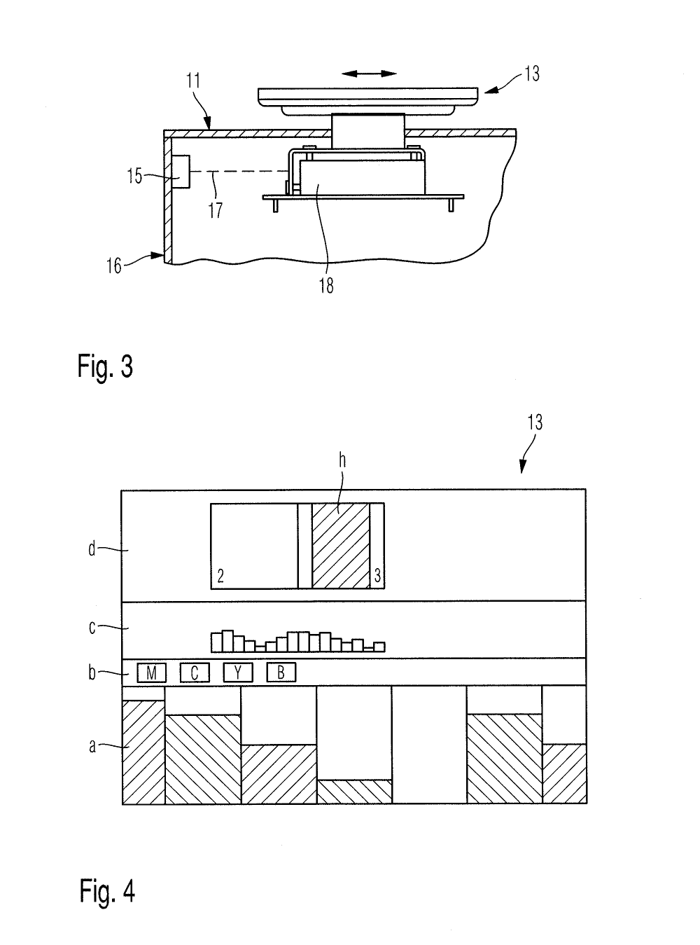

The position of the display and operating element 13 relative to the support 11 can be sensed via at least one sensor 15, wherein in the detail shown in FIG. 3, such a sensor 15 is shown, with the help of which in shifting direction of the display and operating element 13 a lateral distance of the same relative to a lateral portion 16 of the support 11 or a housing receiving the support 11 can be sensed. In FIG. 3, this sensor 15 is formed as a laser sensor, which emits a laser beam 17, wherein this laser beam 17 is reflected on an assembly 18 which is shiftable together with the display and operating element 13, in order to define from this the relative position of the display and operating element 13 relative to the support 11 of the printing press control station 10.

Although in the shown exemplary embodiment the sensor 15 is assigned to the support 11 or a housing of the printing press control station 10 carrying the support 11, it is also possible in contrast with the shown exemplary embodiment to assign the sensor 15 to the display and operating element 13 or the assembly 18 that can be shifted together with the display and operating element 13, thus sensing, with the help of the measurement signal provided by the sensor 15, the lateral distance of the display and operating element 13 or the assembly 18 that is shiftable together with the display and operating element 13 from the lateral portion 16 of the support 11 or a corresponding portion of the housing of the printing press control station receiving the support 11.

Preferred is a variant of the invention, in which either the display and operating element 13 or the assembly 18 that can be shifted together with the display and operating element 13 or the support 11 or the housing of the printing press control station receiving the support 11, are assigned two sensors 15 each, wherein a first sensor 15 senses the distance between the above assemblies in the shifting direction and a second sensor 15 senses a corresponding distance opposite to the shifting direction of the display and operating element 13, wherein via a comparison of these two measurement signals, the function of the sensors 15 can be verified. Because of this, a mutual monitoring and automatic error detection for the two sensors can then be provided.

Although the use of a laser sensor as sensor 15 is preferred, it is also possible to use other sensors for distance measurement such as, for example, potentiometers, in particular control cable potentiometers. In the case of a potentiometer, the position detection takes place by an electrical resistance which changes proportionally to the shifting of the display and operating element 13. In the case of a control cable potentiometer, the electrical resistance changes proportionally to the unwinding length of a cable, which is wound up or unwound with the shifting of the display and operating element 13.

The printing press control station 10 according to the invention furthermore comprises at least one soft-proof monitor 19, which can be shifted along a rear edge 20 of the support 11 which is located opposite the front operating-side edge 14, namely parallel to a rear wall 21 of the control station 11, which extends along the edge 20 of the support 11 located opposite the operating-side edge 14. The or each soft-proof monitor 19 can be automatically shifted along the edge 20 located opposite the operating-side edge 14 adapted to the relative position of the display and operating element 13 relative to the support 11, namely either fully automatically or semi-automatically.

With the fully automatic shifting of the or each soft-proof monitor 19 relative to the support 11, adapted to the relative position of the display and operating element 13, the automatic shifting of the or each soft-proof monitor 19 takes place in such a manner that, when after the shifting of the display and operating element 13 the same stands still for a defined period of time and accordingly has not changed its relative position, the or each soft-proof monitor 19 is automatically shifted relative to the support 11 and adapted to the relative position of the display and operating element 13. With a semi-automatic shifting of the or each soft-proof monitor 19, it is provided that, when after the shifting of the display and operating element 13 on the operating side, a release button or a release switch is actuated and the soft-proof monitor is automatically shifted relative to the support 11, namely adapted to the relative position of the display and operating element 13 relative to the support 11.

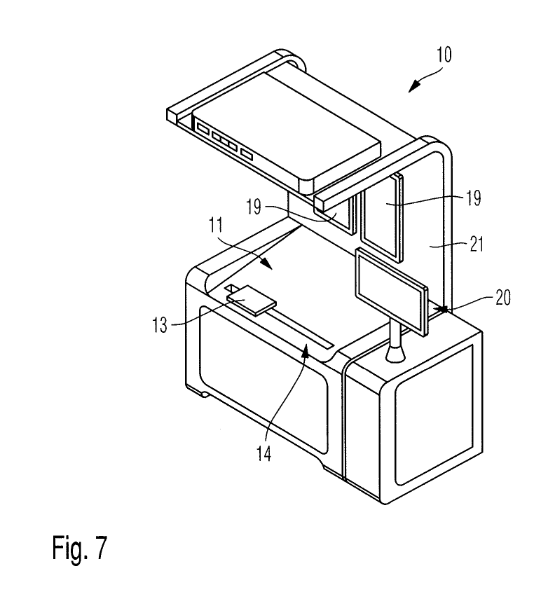

FIGS. 1 and 2 show an exemplary embodiment of a printing press control station 10 according to the invention with a single soft-proof monitor 19, which can be automatically shifted relative to the support 11 to be adapted to the relative position of the display and operating element 13. FIG. 7 shows an exemplary embodiment with two soft-proof monitors 19, which are non-shiftably mounted on the rear wall 21 of the control station 10 of FIG. 7. In contrast with this, it is also possible, however, to automatically displace the two soft-proof monitors 19 to be adapted to the relative position of the display and operating element 13 relative to the support 11.

As already explained, the display and operating element 13 that can be shifted relative to the support 11 is a multi-touch screen, on which, adapted to the relative position of the display and operating element 13 with respect to the support 11, data can be displayed and input, wherein the data that can be displayed and/or input on/in the display and operating element 13 or the multi-touch screen are automatically adapted to the relative position of the display and operating element 13 relative to the support 11.

This is schematically visualised in FIG. 2 by a hatched region 22 of the print copy 12 positioned on the support 11, wherein for the region 22, which is adapted to the position of the display and operating element 13 relative to the support 11 and accordingly relative to the print copy 12 positioned on the support 11, print-relevant data from the display and operating element 13 can be displayed and corresponding data can be input via the display and operating element 13 for this region 22.

FIG. 4 visualizes a first display on the display and operating element 13 for such a region 22 of a print copy 12, wherein in a part region a in FIG. 4 current adjusting parameters for ink key adjusting elements are displayed, which are assigned to the region 22 of the print copy 12. These current adjusting parameters in the part region a relate to a printed printing ink, wherein by touching corresponding soft keys in the part region b of the display of FIG. 4 it is possible to change backwards and forwards between the four process colors magenta (m), cyan (c), yellow (y) and black (b) in order to display and change if required the adjusting parameters of the ink key adjusting elements of the corresponding region 22 for the individual process colors in the part region a. In the part region a, adjusting parameters of damp adjusting elements can also be displayed and changed if required alternatively to the ink key adjusting elements. In the part region c of the display of FIG. 4, adjusting parameters of all ink key adjusting elements are shown reduced in size on the display and operating element 13 over the entire width of the print product 12, namely again for the process color selected in the part region b. In the part region d of the display of FIG. 4, print pages 2 and 3 are shown, namely the print page 2 and 3 which correspond to the print copy 12 placed on the support 11. Therein, the part region h, which is shown hatched in the part region d, corresponds to the region 22 of the print copy 12 for which dependent on the relative position of the display and operating element 13 relative to the support 11, print-relevant process parameters can be displayed and/or adjusted relative to the support 11 in the part region a.

As already explained, the display and operating element 13 is a multi-touch screen, in the case of which the display can be changed and data input through touching, tipping, pulling or wiping and through compression movements and pulling-open movements. Thus, by touching individual segments of the part region a for example and by pulling upwards or pulling downwards on touching these segments an adjusting parameter for the corresponding ink key adjusting elements can be adapted. In the part region d, changing between individual print pages is possible through a wiping movement. In the part region a and/or in the part region d, the display scale can be compressed or enlarged through a compression movement by pulling together two fingers or an expansion movement by moving two fingers away from each other.

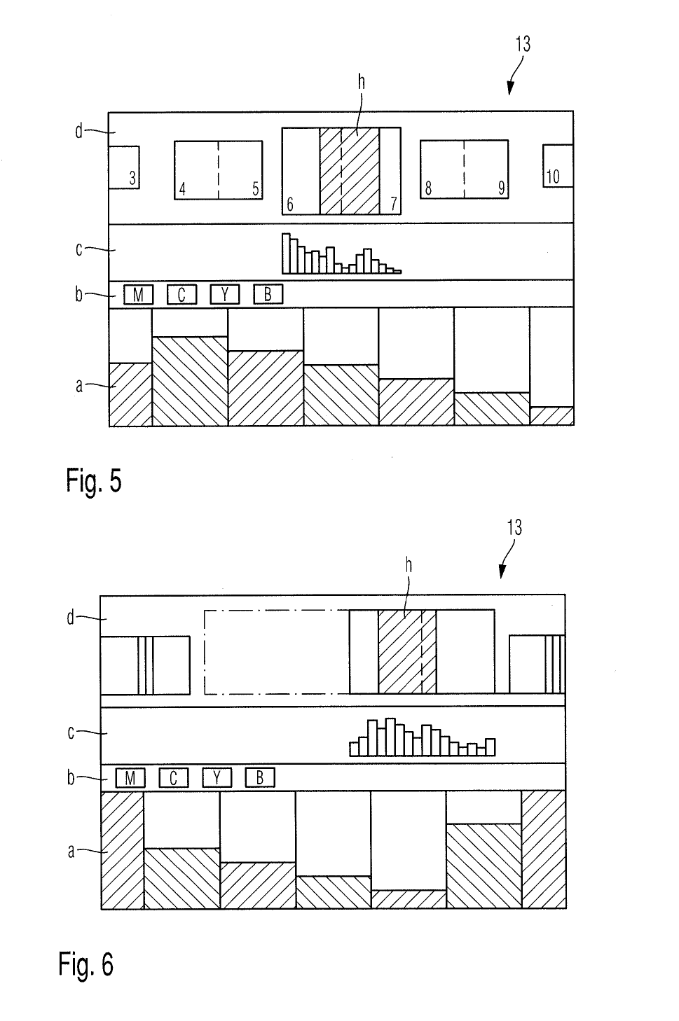

In the exemplary display according to FIG. 5 of the display and operating element 13, not only the print pages (in this case print pages 6 and 7) of the print sheet currently placed on the support 11 are displayed in the part region d, but rather additionally adjacent print page pairs and other print sheets of a printed newsprint product, wherein through a wiping movement in the part region d it is possible to change backwards and forwards between the individual print page pairs, and wherein the respective selected print page pair is displayed enlarged in a middle segment of the part region d relative to the other print page pairs. By wiping or pulling, as already mentioned, it is possible to change backwards and forwards between the individual printing page pairs. In FIG. 5, the part region h for the currently selected printing page pair, which corresponds to the print copy placed in the tray 11, in turn is emphasised by hatching, wherein for this part region h in the part region a adjusting parameters of ink key adjusting elements of a process color selected in the part region b are displayed. In the part region c, in turn, all adjusting parameters of all ink key adjusting elements of the process color correspondingly selected in the part region b are displayed over the entire printing page pair or over the entire print copy.

FIG. 6 visualizes a further alternative display on the display and operating element 13, wherein in the part region d in contrast with the variants of FIGS. 4 and 5, no print pages or print page pairs are displayed, but rather front and back pages of the individual print sheets. Such a display is advantageous in particular with illustration printing presses.

In contrast with the representations according to product pages or front and back pages of print sheets described in FIGS. 4 to 5, a physical, machine-based display and selection can also take place in particular in the part region d of the respective displays on the display and operating element 13, namely such that individual printing press units such as for example printing couples of the printing press are displayed, which can then be selected by tipping or pulling into a defined position in order to display and/or change adjusting parameters in the part region a corresponding to the selected printing couples.

As already explained, the display and operating element preferentially is a multi-touch screen, in which all adjusting possibilities of a multi-touch screen known from practice such as tipping, double-tipping, pulling and wiping can be utilized. Furthermore, a simultaneous operation of a plurality of units or a simultaneous parameter input for a plurality of adjusting elements independently of one another is possible in particular.

### LIST OF REFERENCE NUMBERS

10 Printing press control station
11 Support
12 Print copy
13 Display and operating element
14 Front edge
15 Sensor
16 Portion
17 Laser beam
18 Assembly
19 Soft-proof monitor
20 Rear edge
21 Rear wall
22 Region

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A printing press control station, comprising:
a support for a print copy;
a display element, wherein the display element is shiftable along a front edge of the support and wherein the display element is a combined display and operating element for displaying and inputting data; and
a sensor, wherein the sensor is disposed on the display element, or on an assembly that is shiftable together with the display element, or on the support, or on a housing of the support, and wherein a distance of the display element or the assembly from a lateral portion of the support or the housing is sensable by the sensor to define a relative position of the display element with respect to the support;
and wherein data displayable and inputtable with the display element is automatically adaptable to the relative position of the display element with respect to the support.

2. The printing press control station according to claim 1, wherein the print copy is a print sheet or a portion of a printed substrate web.

3. The printing press control station according to claim 1, further comprising a second sensor, wherein the second sensor is disposed on the display element, or on the assembly, or on the support, or on the housing, wherein the sensor senses a distance in a shifting direction of the display element, and wherein the second sensor senses a distance opposite to the shifting direction.

4. The printing press control station according to claim 1, wherein the sensor is a laser sensor.

5. The printing press control station according to claim 1, wherein the sensor is a potentiometer.

6. The printing press control station according to claim 5, wherein the potentiometer is a control cable potentiometer.

7. The printing press control station according to claim 1, wherein the display element is a multi-touch screen.

8. The printing press control station according to claim 1, further comprising a soft-proof monitor which is disposed on a rear edge of the support, wherein the rear edge is located opposite from the front edge, and wherein the soft-proof monitor is shiftable along the rear edge to a position corresponding to the relative position of the display element with respect to the support.

9. The printing press control station according to claim 8, wherein the soft-proof monitor is automatically shiftable to the position such that, after displacing the display element to the relative position and after the display element does not move from the relative position for a defined period of time, the soft-proof monitor is shiftable to the position.

10. The printing press control station according to claim 8, wherein the soft-proof monitor is semi-automatically shiftable to the position such that, after displacing the display element to the relative position, a release button or a release switch is actuated and the soft-proof monitor is shiftable to the position.

11. A printing press control station, comprising:
a support;
a display element, wherein the display element is movable along the support and wherein the display element is a combined display and operating element for displaying and inputting data; and
a sensor, wherein the sensor is associated with the display element or the support and wherein a distance of the display element from the support is sensable by the sensor to define a relative position of the display element with respect to the support;
wherein data displayable and inputtable with the display element is automatically adaptable to the relative position of the display element with respect to the support.

12. A method for operating a printing press control station, comprising the steps of:
moving a display element along a support, wherein the display element is a combined display and operating element for displaying and inputting data;
sensing a distance of the display element from the support by a sensor to define a relative position of the display element with respect to the support, wherein the sensor is associated with the display element or the support; and
automatically adapting data displayable and inputtable with the display element based on the relative position of the display element with respect to the support.
